(19) United States
(12) Patent Application Publication
(10) Pub. No.: US 2026/0173574 A1
(43) Pub. Date: Jun. 18, 2026

(54) PHOTOVOLTAIC DEVICE AND METHOD FOR MANUFACTURING THE SAME

(71) Applicant: MEYER BURGER (GERMANY) GMBH, Hohenstein-Ernstthal (DE)

(72) Inventors: Till KÖSSLER, Morges (CH); Loris BARRAUD, La Chaux-de-Fonds (CH)

(21) Appl. No.: 19/128,872

(22) PCT Filed: Nov. 10, 2023
(86) PCT No.: PCT/EP2023/081424

§ 371 Date: May 9, 2025

(30) Foreign Application Priority Data
Nov. 10, 2022 (EP) 22206779.5

(51) Int. Cl. H10F 77/20

(52) U.S. Cl. CPC H10F 77/219

(57) ABSTRACT

An interdigitated back contact (IBC) photovoltaic device having first-type charge collecting structures and second-type charge collecting structures including a first-type doped structured semiconducting layer consisting in a plurality of n- or p-doped portions and a second-type doped semiconducting layer of the other doped-type of said first-type doped layer. On the doped semiconducting layer, a continuous, electrically conductive, multifunctional protection layer is arranged, to protect the semiconducting layer, and having a highest metal ion diffusion coefficient, that is, at the same temperature, lower than the lowest metal ion diffusion coefficient, so that the multifunctional protection layer is less vulnerable to physical and chemical degradation than the to be protected semiconducting layer. On the multifunctional protection layer, a structured charge collecting layer stack is arranged with vertical trenches to separate electrically the first-type charge collecting structures and the second-type charge collecting structures. This layer stack includes at least one conductive layer.

### TECHNICAL FIELD

The present invention relates to the field of photovoltaic devices. More particularly, it relates to a photovoltaic device made of crystalline silicon with back-contacts being of the interdigitated back contact (IBC) type in which the collecting material is patterned, resulting in a device comprising both type of contacts on the back side of the device. More precisely, the invention relates to IBC and HJT-IBC photovoltaic devices that have an improved reliability and greater lifetime. The invention also relates to a method for producing such photovoltaic devices.

A particular advantageous application of the present invention is for the low-cost production of highly efficient and highly reliable photovoltaic cells having improved reliability, intended for generating electrical energy, but the invention also applies, more generally, to any similar device in which an incoming radiation is converted into an electrical signal, such as photodetectors and ionizing radiation detectors.

### BACKGROUND OF THE INVENTION

Interdigitated back-contact silicon solar cells (IBC), while being highly efficient, all present reliability problems due to possible chemical or environmental corrosion linked to their design which requires a highly complex processing. Indeed, the realization of IBC devices requires localizing or patterning of the semiconducting p- and n-type contacts and of the according conducting contact structures into interdigitated, alternating structures, with a very high accuracy.

Most of the techniques known from the state-of-the-art rely on the use of complex and costly processes. Various methods are known to realize the alternating p- and n-type structures. They can be based on localized diffusion methods, mechanical masking technics or even lithographic technics with partial back etch of non-localized depositions.

Recently, highest efficiencies have been demonstrated in crystalline silicon IBC cells based on heterojunction contacts.

Examples are described in for example the following publications:
Interdigitated Back Contact Silicon Heterojunction Solar Cells, J. C. Stang, Thesis TU Berlin 2018
Efficient interdigitated back-contacted silicon heterojunction solar cells, N. Mingirulli et al, Phys. status solidi-Rapid Res. Lett., vol. 5, nr.4, pp. 159-161, April 2011;
The role of back contact patterning on stability and performance of Si IBC heterojunction solar cells, U.K.DAS et al., Proceedings of the 40 the IEEE Photovoltaic Specialist Conference, 2014, vol. 1.

Several attempts have been undertaken in the past to reduce the cost of IBC-HJT devices without really addressing the issue of short-term and long-term reliability induced by for example corrosion. Most of the reliability problems have their origin by chemical damages due to metallization and etching steps.

For example, in document EP1519422B1 it has been proposed to pattern only a first silicon layer which is an n-doped layer or a p-doped layer, i.e., an electron- or a hole-collecting structure. A second silicon layer of a second type is, in these devices, deposited on top of the patterned charge-collecting structures. The resulting device is called a “tunnel junction IBC-HJT device”. Although the fabrication process of such devices is simpler than the ones in which both of the charge carrier collecting types are structured, such as for example in the case of the device described in U.S. Pat. No. 6,274,402B1, tunnel junction IBC-HJT devices may present long-term reliability problems because of the possible corrosion of the n-doped layer or p-doped PEVCD layers.

In order to improve IBC solar cells, the document WO 2022/084205A1 proposes a simplified process to realize conducting contact structures that are less expensive to manufacture while at the same time assuring an improved efficiency. Nevertheless, the devices described in WO 2022/084205A1 might suffer also, from a reliability problem related to the fact that the silicon PECVD layers are sensitive to chemical corrosion, in-diffusion from metal contacts or environmental deterioration such as induced by humidity for example. Similar to WO 2022/084205A1, the devices described in US 2015/072467A1 and US 2021/159355A1 have a structure that make the passivation layers and the doped layers sensitive to chemical corrosion or environmental deterioration.

Furthermore, not all the physical and chemical corrosion and environmental deterioration effects of the PECVD layers in produced IBC cells are fully understood, which can lead to a non-controllable reduction in the production efficiency and/or a deterioration of the devices after they have been put on the market, so becoming an issue of guaranteed quality of the devices.

There is thus a need for an IBC photovoltaic cell that is based on a low-cost process, that has improved efficiency and that should be less sensitive to the possible short-term and/or long-term degradation of the PECVD layer of the IBC and so providing a more reliable IBC cell.

### SUMMARY OF THE INVENTION

The present invention relates to a photovoltaic device which allows to alleviate the disadvantages of the prior art. In particular, the invention of integrating a multifunctional protection layer allows to protect against considerable possible chemical and/or physical degradation of the doped n or doped p silicon PECVD layers. These layers are fragile and may be easily degraded, for example by humidity. The multifunctional protection layer protects the PEVCD layers so that the reliability and lifetime of IBC solar cell is improved. The multifunctional protection layer is deposited as an electrically conductive and non-structured layer and covers the sensitive silicon layers. The functionality of the multifunctional protection layer is hence to transfer the electrical charges from the doped silicon contact structures to the structured charge collecting structures and at the same time establishing a physical and/or chemical protective layer for the fragile PECVD silicon layer. It has to be mentioned that the properties of this multifunctional protection layer is a compromise between a sufficient charge transfer between the two different doping types of the silicon collecting structures their related conductive charge collecting structures, and a leakage current between those charge collecting structures of opposite types, and as well a sufficient thickness of the multifunctional protection layer to fulfill the protective effect. It has been found that by selecting an optimized electrical conductivity, an optimized thickness, and an appropriate material of the multifunctional protection layer, a solar cell device with only minor losses in solar cell efficiency can be realized by at the same time enhanced resistance to physical and chemical degradation effects.

In a first aspect, the invention is realized by an interdigitated back contact (IBC) photovoltaic device having first-type charge collecting structures (IS1) and second-type charge collecting structures (IS2). The photovoltaic device comprises a substrate and a doped semiconducting layer, arranged on said substrate, comprising a first-type doped structured semiconducting layer consisting in a plurality of n- or p-doped portions and a second-type doped semiconducting layer, of the other doped-type of said first-type doped layer. The said substrate defines a vertical direction (Z) orthogonal to its plane and a lateral direction (X,Y) in its plane.

On said semiconducting layer, a continuous, electrically conductive, multifunctional protection layer is arranged to protect said semiconducting layer. The multifunctional protection layer has, for a predetermined metal ion, a highest metal ion diffusion coefficient D1, that is lower than the lowest metal ion diffusion coefficient D2 in a semiconducting layer, for example in a semiconducting silicon layer. By the particular property of lower metal ion diffusion coefficient, the multifunctional protection layer is less vulnerable to physical and chemical degradation than the to be protected semiconducting layer. In consequence, the semiconducting layer becomes better protected against physical and chemical degradation.

The predetermined metal ion can be ions of any electrically conductive metal, for example copper, aluminium, zinc, tin or nickel.

The reduction of degradation is mostly due to the fact that the multifunctional protection layer has a lower metal ion diffusion coefficient than the semiconducting layer, preferably under temperatures between −20° C. to 200° C., preferably between room temperature (25° C.) and 200° C.

The diffusion coefficients D1, D2 defined herein are calculated as:

$${D}_{1 , 2} = {D}_{01 , 02} ( e \frac{( - {E}_{a 1 , 2} )}{k T} ) \qquad ( 1 )$$

Herein, the parameters are defined as following:
D1: diffusion coefficient of a specific metal ion in a material 1 of a layer 1, here the multifunctional layer
D2: diffusion coefficient of a specific metal ion in a material 2 of a layer 2, here the semiconducting layer
D_{01,02}: pre-exponential diffusion-factor for metal ions in material 1, 2
E_{a1,2}: activation Energy of according metal ion diffusion in material 1, 2
K: Boltzmann constant
T: Temperature in Kelvin

In an exemplary realization, the diffusion coefficient D1 of copper ions (Cu⁺) in a multifunctional protection layer made of ZnO is lower than its diffusion coefficient D2 in the semiconducting layer at the same temperature.

On said multifunctional protection layer, a structured charge collecting layer stack is arranged, comprising vertical trenches to separate electrically the first-type charge collecting structures and the second-type charge collecting structures. This layer stack comprises at least one conductive layer.

In embodiments the photovoltaic device comprises on top of the patterned layer stack a patterned isolating resist layer comprising first type and second type apertures, the second-type apertures in the isolation resist layer defining said trenches.

In embodiments the photovoltaic device comprises conducting pads that are arranged on said resist layer and that extend, in said first type apertures, up to and in contact with said layer stack.

In embodiments, for a chosen metal ion, D1 is lower than 0.9×D2, preferably lower than 0.75λD2, or lower than 0.5×D2, more preferably lower than 0.2×D2.

In embodiments, the metal ion diffusion coefficient D1 of the protection layer 8 is lower than 5×10⁻¹⁰ cm²s⁻¹, preferably lower than 2×10⁻¹⁰ cm²s⁻¹ or more preferably lower than 2×10⁻¹⁰ cm²s⁻¹ at a temperature between 0° C. and 200° C.

In variants, the ion diffusion coefficient D1 is substantially homogeneous, i.e. in a plane of the protection layer D1 is equal, within an error of less than 10%, of the ion diffusion coefficient D1 orthogonal to any virtual plane of the protection layer.

In variants, the ion diffusion coefficient D1 in a plane of the protection layer may be different than the ion diffusion coefficient D1 orthogonal to any virtual plane of the protection layer. In any case, for a predetermined metal ion the greatest value of D1 is smaller than the smallest diffusion coefficient of the electrically conductive layer defined in any direction in the electrically conductive layer.

The higher resistance against physical and chemical degradation of the multifunctional protection layer implies that this protection layer has a higher resistance to oxidation and/or alkaline corrosion than the semiconducting layer. In a variant the higher resistance against physical and chemical degradation due to a higher resistance to oxidation and/or acidic corrosion of the multifunctional layer compared to the semiconducting layer.

On said multifunctional protection layer, a structured charge collecting layer stack is arranged, comprising vertical trenches to separate electrically the first-type charge collecting structures IS1 and the second-type charge collecting structures IS2. This layer stack comprises at least one of a conductive layer.

In an embodiment, said multifunctional protection layer has an electrical resistivity between 0.005 Ohm*cm and 20000 Ohm*cm, preferably between 0.01 Ohm*cm and 10000 Ohm*cm, even more preferably between 0.05 Ohm*cm and 5000 Ohm*cm.

In an embodiment, the multifunctional protection layer provides low electrical contact resistance between the semiconducting layer and said layer stack, said low electrical contact resistance being preferably less than 1000 mOhm*cm², preferably less than 500 mOhm*cm².

In an advantageous embodiment, said multifunctional protection layer is a transparent layer having an optical transparency T at least in a wavelength range between 900 nm and 1200 nm. In embodiments the transparency T is higher than 50%, preferably higher than 75%, or more preferably higher than 90%.

In an embodiment, said multifunctional protection layer is a reflective layer having a reflectivity R higher than 10%, preferably higher than 20%, or higher than 30%, at least in a wavelength range between 900 nm and 1200 nm.

In an embodiment, the multifunctional protection layer is made of an electrically isotropic material.

In an embodiment, the multifunctional protection layer is made of an electrically anisotropic material, wherein the conductivity of the material is higher in Z-direction than in the X, Y plane direction.

In an embodiment, the multifunctional protection layer comprises at least two different sublayers.

In an embodiment, the multifunctional protection layer is made, at least partially, of at least one of: TiNx, TiOx, TiOxNy, SnO2, SnOx, ZnO, ZnSNxOy, ITO, IO, IZO, IWO, WO, IZrO, NiO, TaN, TaOx and TiZrxNy, ICO, MoOx, wherein 0<(x, y)≤3.

In an embodiment, the multi-functional layer is doped with at least one of the following elements: Sb, F, Al, In, Ga, Mg, B, P, Zn, Ta, Y, Ce, H.

In an embodiment, the thickness of said multifunctional protection layer is between 1 nm and 1 μm, preferably between 1 nm and 500 nm, more preferably between 1 nm and 200 nm, even more preferable between 10 nm and 200 nm. In variants the multifunctional protection layer may have a thickness higher than 1 μm or smaller than 1 nm.

The invention is also achieved by a photovoltaic system comprising at least two interdigitated back contact (IBC) photovoltaic devices, as described herein, that are interconnected by conductors and wherein conducting pads of the first type of the first cell are connected to conducting pads of the second type of the second cell by that establishing a series connection of accordingly connected devices or wherein conducting pads of the first or second type of the first cell are connected respectively to conducting pads of the first or second type of the second cell and by that establishing a parallel connection of accordingly connected devices.

In another aspect, the invention is also achieved by a method for manufacturing an interdigitated back contact (IBC) photovoltaic device 1, as described herein, the method comprising the steps (A-F) of:
Step A: providing a substrate of a first- or second type doping being an n-type or a p-type doping and having a front side and a back side and realizing on said back side a first n- or p doped semiconducting layer comprising individual doped portions of said first-type doping and a second doped semiconducting layer of a second-type doping, being of the other type p- or n than said first type doping, to provide alternating electrical charge-types of semiconducting contacts.
Step B: realizing an electrically conductive multifunctional protection layer on top of said doped semiconducting layer, the multifunctional protection layer having a metal ion diffusion coefficient D1, that is lower than the metal ion diffusion coefficient D2 at the same temperature in said semiconducting layer at the same temperature, so that the multifunctional protection layer is less vulnerable to physical and/or chemical degradation than the to be protected semiconducting layer;
Step C: realizing, on said multifunctional protection layer, a stack of layers comprising at least one conductive layer;
Step D: realizing on said layer stack, a patterned resist layer, so that the patterned resist layer comprises resist parts and resist apertures;
Step E: applying a plurality of conductive pads onto said resist layer, and so that the conductive pads fill said resist apertures, making electrical contact to said conductive layer stack;
Step F: etching of the stack of layers in areas specified by apertures in the isolation resist layer so as to create trenches having a minimal width w to electrically separate first type charge collecting structures IS1 from second type charge collecting structures IS2.

In embodiments of the method, the multifunctional protection layer is made, at least partially, of at least one of: TiNx, TiOx, TiOxNy, SnOx, ZnO, ZnSNxOy, ITO, IO, IZO, IWO, WO, IZrO, NiO, TaNx, TaOx, TiZrxNy, ICO, MoOx, and wherein 0< (x, y)≤3, i.e. x and y are values between 0 and 3, possibly being equal to 3.

In embodiments of the method, the multifunctional layer is doped with at least one of the following elements: Sb, F, Al, In, Ga, Mg, B, P, Zn, Ta, Y, Ce, H.

### BRIEF DESCRIPTION OF THE DRAWINGS

The present invention will now be described in reference to the enclosed drawings where:

FIG. 1 illustrates a perspective view of an IBC device comprising a multi-functional protection layer, being a conductive protective layer, and illustrates the 2D layout of charge collecting fingers in the horizontal plane of an isolation layer at the backside of a device of the invention;

FIG. 2 illustrates a vertical cross-section along an outlined cut along a line A-A illustrated in FIG. 1, also demonstrating the various apertures and openings in an isolation layer, before depositing contact pads and before back etch, as well as an embodiment of an arrangement of a first semiconducting layer being a first-type n- or p doped layer and a second-type doped semiconducting layer of the opposite doping type p- or n, said first and second doped semiconducting layers being arranged side by side;

FIG. 3 illustrates a vertical cross-section along the outlined cut A-A in FIG. 1, projected on a virtual X-Z plane, of an embodiment of the device according to the invention, wherein the charge collecting structures comprise a stack of layers comprising at least a multifunctional protection layer in contact with a doped semiconducting layer and at least one of a TCO layer and/or a metal layer;

FIG. 4 illustrates a vertical cross-section, projected on a virtual X-Z plane, of an embodiment of the device according to the invention, wherein a multifunctional protection layer is made of two sublayers and wherein the charge collecting structures comprise a stack of layers comprising at least one of a TCO layer and/or a metal layer;

FIG. 5 illustrate a vertical cross-section, projected on a virtual X-Z plane, of an embodiment of the device according to the invention, wherein the charge collecting structures comprises a multifunctional protection layer in contact with a doped semiconducting layer and with a metallic layer;

FIG. 6 shows a graph of simulation results of calculations of the relative efficiency losses in function of the resistivity of a multifunctional protection layer for 3 different 20 layer thicknesses. The results show, for different thicknesses t of 5 nm (Δ), 22 nm (¤) and 100 nm (0) that the relative efficiency loss, expressed in %, is minimal for a certain resistivity of the multifunctional protection layer.

### DETAILED DESCRIPTION

The present invention will be described with respect to particular embodiments and with reference to certain drawings, but the invention is not limited thereto. The drawings described are only schematic and are non-limiting. In the drawings, the size of some of the elements may be exaggerated and not drawn on scale for illustrative purposes. The dimensions and the relative dimensions do not correspond to actual reductions to the practice of the invention.

It is to be noticed that the term “comprising” in the description and the claims should not be interpreted as being restricted to the means listed thereafter, i.e. it does not exclude other elements.

Reference throughout the specification to “an embodiment” means that a feature, structure, or characteristic described in relation with the embodiment is included in at least one embodiment of the invention. Thus, appearances of the wording “in an embodiment” or, “in a variant”, in various places throughout the description are not necessarily all referring to the same embodiment, but several. Furthermore, the features, structures or characteristics may be combined in any suitable manner, as would be apparent to a skilled person from this disclosure, in one or more embodiments. Similarly, various features of the invention are sometimes grouped together in a single embodiment, figure, or description, for the purpose of making the disclosure easier to read and improving the understanding of one or more of the various inventive aspects. Furthermore, while some embodiments described hereafter include some, but not other features included in other embodiments, combinations of features if different embodiments are meant to be within the scope of the invention, and from different embodiments. For example, any of the claimed embodiments can be used in any combination. It is also understood that the invention may be practiced without some of the numerous specific details set forth. In other instances, not all structures are shown in detail in order not to obscure an understanding of the description and/or the figures.

A horizontal plane herein is defined as a X-Y plane parallel to a face of the substrate 2. The X-Y plane is defined by two orthogonal horizontal axes X and Y. The wording “horizontal cross section means a cross section in a X-Y plane. The wording “vertical means” here perpendicular to the substrate 2 and defines a Z-axis. A vertical cross section is a cross section in a X-Z or Y-Z plane that comprises the vertical axis Z. A lateral direction is defined in an X and/or Y direction in a horizontal plane.

A longitudinal direction is defined as being a direction substantially in the length of conducting wires, the conducting wires not being necessarily straight wires but may have a sinusoidal shape or comprise curves or steps. A lateral direction is defined as being a direction orthogonal to the longitudinal direction.

A width is defined as a width of a structure across a virtual line in a horizontal plane. Thicknesses are defined herein as thicknesses in the vertical Z-direction.

The term “full area layer” used herein is defined as a layer deposited on a whole surface in a horizontal X-Y plane, for example of a whole surface parallel to a substrate.

The back side of a photovoltaic cell as described herein is the side opposite to the illumination side of the photovoltaic cell.

Horizontal and vertical electrical resistance means the resistance in respectively an X-Y plane and vertical X-Z or Y-Z plane.

The invention provides an IBC solar cell 1, such as a crystalline silicon IBC photovoltaic devices that can be produced with a low-cost process especially in high volume production machines. IBC cells as described herein comprise also IBC cells comprising a tunnel junction.

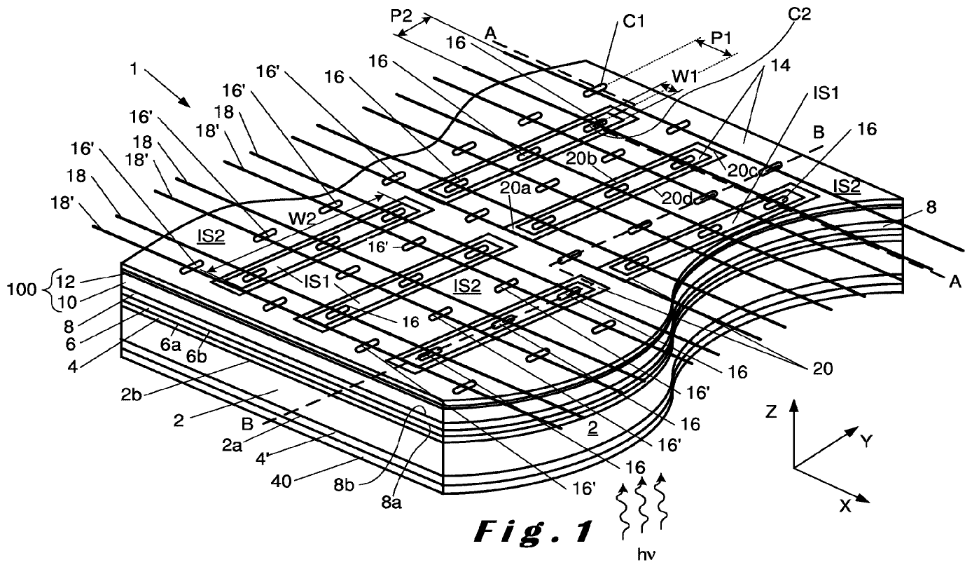

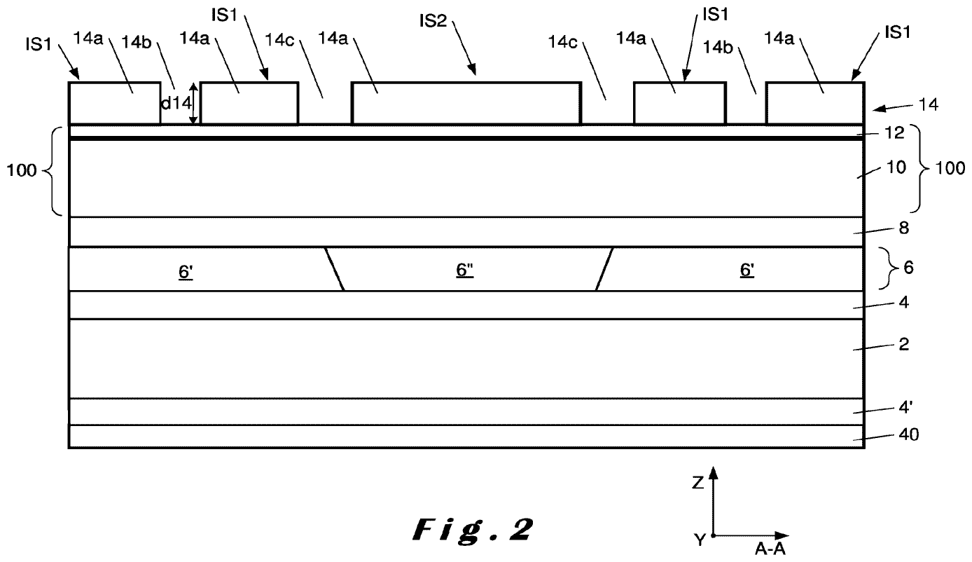

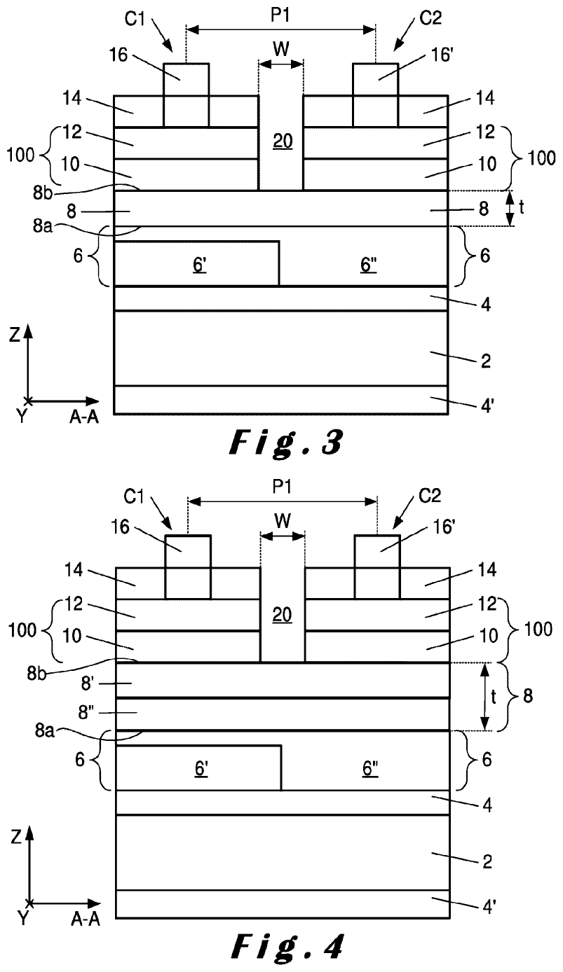

In a first aspect, the invention is achieved by an interdigitated back contact (IBC) photovoltaic device 1 having first-type charge collecting structures IS1 and second-type charge collecting structures IS2 that are electrically separated by trenches 20. As illustrated in FIGS. 1-4, charge collecting structures IS1, IS2, also defined as charge collecting finger, are the stack of layers 100 that collect the electrical charges, that, in preferred executions, include conductive pads 16, 16′.

The photovoltaic device comprises a substrate 2 made of crystalline silicon.

The substrate 2 can comprise to each side 2a, 2b a buffer layer 4, 4′. These buffer layers 4, 4′ are used as passivation layers on the silicon substrate 2 to reduce the recombination rate at the silicon surface. Those buffer layers 4, 4′ can be chosen and adapted to its particular tasks. For example, the buffer layer 4′, being deposited on the front side of the solar cell, can be of high transparency T (T>60% or T>80% in the visible and/or the infrared part of the electromagnetic spectrum). The buffer layer 4′ at the front side doesn't necessarily need a high carrier transfer efficiency. For this purpose, for example, a hydrogenated amorphous silicon a-Si:H, a hydrogenated SiO, SiC, SiN or AlOx layer, of a combination thereof, can be used. Such layers are typically intrinsic or only slightly doped for most efficient passivation effects. On the rear side the optional buffer layer 4 can advantageously be a highly transparent passivation layer that also efficiently can transfer electric charges. For this purpose, intrinsic amorphous silicon layers are preferred choices. In variants, only slightly doped hydrogenated amorphous silicon layers can be used. But any layer that can offer above mentioned features can be used for this purpose. Slightly doped hydrogenated amorphous silicon means a dopant concentration below 10¹⁹ cm⁻³.

The photovoltaic device 1 also comprises, arranged to said substrate 2 to the side opposite to the incident light side, possibly to the buffer layer 4 at the back side, a semiconducting layer 6 comprising a first-type doped semiconducting layer consisting in a plurality of n- or p-doped portions 6′ and a second-type doped semiconducting layer 6″, consisting of a plurality of the other doped-type p- or n of said first-type doped layer 6′. In a HJT IBC tunnel-junction device the second-type doped semiconducting layer 6″ is at least partially covering the portions 6′, and in an embodiment, for a simpler production process, even fully covering the first-type doped portions 6′. The substrate 2 defines a vertical direction Z orthogonal to its plane and a lateral direction X, Y in its plane. The positive Z direction is defined from the substrate 2 to the electrical contacts 16, 16′.

On said semiconducting layer 6, a multifunctional protection layer 8 is arranged. A multifunctional protection layer 8 herein, also defined as multifunctional layer, is a protection layer that provides not only protection properties against physical and chemical degradation of the doped semiconducting layer 6 but also has additional properties such as, at least, electrical properties, for example a minimized contact resistance to the layers it is in contact with and a resistance low enough to transfer the electric charges from semiconducting layer 6 to the charge collecting layer 100 with minimized ohmic losses but a high enough resistance to also achieve minimized photoconversion losses due to a current shunt leakage between neighboring contact structures IS1, IS2. Those losses should be less than 1% and even better, less than 0.1%. The loss being defined as the relation of a solar cell efficiency with and without a multifunctional protective layer 8.

It has been identified by the applicant that the reduction of physical and/or chemical degradation is essentially due to the fact that the multifunctional protection layer 8 has a lower metal ion diffusion than in the semiconducting layer 6.

In embodiments the metal ion diffusion coefficient D1 in the multifunctional layer 8 of a predetermined type of metal ion is lower than the metal ion diffusion coefficient D2 of that metal ion in the semiconducting layer 6.

The diffusion coefficients D1, D2 defined herein are calculated as:

$${D}_{1 , 2} = {D}_{01 , 02} ( e \frac{( - {E}_{a 1 , 2} )}{k T} ) \qquad ( 1 )$$

Herein, the parameters are defined as following:
D1: diffusion coefficient of a specific metal ion in the material 1 of a layer 1, here the multifunctional layer 8
D2: diffusion coefficient of a specific metal ion in the material 2 of a layer 2, here the semiconducting layer 6
D_{01,02}: pre-exponential diffusion-factor for metal ions in material 1, 2
E_{a1,2}: activation Energy of according metal ion diffusion in material 1, 2
K: Boltzmann constant
T: Temperature in Kelvin

In an exemplary realization, the diffusion coefficient D1 of copper ions (Cu⁺) in a multifunctional protection layer 8 made of ZnO is lower than its diffusion coefficient D2 in the semiconducting layer 6 at the same temperature.

In embodiments, for a chosen type of metal ion, D1 is lower than 0.9×D2, preferably lower than 0.75×D2, or lower than 0.5×D2, more preferably lower than 0.2×D2, even more preferable lower than 0.1×D2. D1 may be lower than 0.01×D2 or several magnitudes lower than the diffusion coefficient D2.

In an exemplary execution of the device, the metal ion diffusion coefficient D1 of the protection layer 8, in an environment having a temperature between 0° C. and 200° C., may be lower than 5×10⁻¹⁰ cm²s⁻¹, or lower than 2×10⁻¹⁰ cm²s⁻¹ or preferably lower than 2×10⁻¹⁰ cm²s⁻¹.

In variants, the metal ion diffusion coefficient D1 in a plane of the protection layer 8 is substantially homogeneous, i.e. within an error of less than 10%, of the ion diffusion coefficient D1 orthogonal to any virtual plane of the protection layer.

In embodiments, the higher resistance against physical and chemical degradation of the multifunctional protection layer 8 implies that it has a higher resistance to oxidation or alkaline corrosion or acidic corrosion than the semiconducting layer 6. In variants the corrosion may be due to etching of the layers, for example etching due to errors in the handling of a finished wafer in a harsh chemical environment, which may be, for example, a local atmosphere having a high alkaline level or a high acidity level.

In embodiments the reduced damage because of for example alkaline or acid etching may result in a reduced effect on the surface and/or quality of the layer, for example a reduced effect on the rugosity or porosity of the protection layer 8 relative to the effect on the semiconducting layer 6.

The multifunctional protection layer 8 has a front side 8a to the side of the substrate 2 and a back side 8b opposite to said front side 8a. The multifunctional protection layer 8 is preferably a continuous, full-area layer.

The multifunctional layer 8 has a higher resistance against environmental degradation, chemical etching, and metal ion diffusion. Said higher resistance of the multifunctional layer 8 is greater than the one of the doped silicon layer 6.

This higher resistance against environmental degradation has been demonstrated experimentally by the inventors, by an accelerated degradation test on comparative solar cell samples with and without integrating a multifunctional protective layer MFL, as shown in table 1. The degradation test used in this test has been done on an encapsulated solar cell in an atmosphere of 85% relative humidity at an elevated temperature of 85° C., also specified as damp heat 85/85 test.

The experimental result show clearly that the multifunctional protection layer 8 improves considerably the reliability of IBC photovoltaic cells.

TABLE 1

| Test sample | Damp heat hours | Rel. efficiency loss |
|---|---|---|
| Without MFL layer | 480 | −21.5% |
| With MFL layer | 480 | −0.6% |

The multifunctional protection layer 8 can have an optical transparency T, at least between 900 nm and 1200 nm. The optical transparency can have any value. The transparency T is preferably higher than 50%, more preferably higher than 75%, or higher than 90%.

The multi-functional layer 8, arranged on a semiconducting layer 6, can have an optical reflectivity R at least between 900 nm and 1200 nm. The reflectivity is higher than 10%, preferably higher than 20%, or higher than 30%. The reflectivity R allows to convert photons that are transmitted through the semiconducting layer and that were not absorbed. A high reflectivity can be desired in, for example, non-bifacial photovoltaic cells.

The functionality of the multifunctional protection layer 8 is to protect physically and chemically the semiconducting layer 6 of the solar cell in a photovoltaic module which otherwise might become in contact or directly exposed to metal, polymers such as encapsulate materials, humidity and/or chemicals that are either mixed as additives to said polymers and/or are produced by degradation effects of the polymer compound.

As an example, environmental pollution such as acidic rain or an atmosphere charged with hydrocarbons may be a source of degradation of a photovoltaic device when fixed outdoors of a building.

Therefore, the multifunctional protection layer 8 has to be as impermeable to moisture or chemical substances and be as inert as possible. The multifunctional protection layer 8 must also allow vertical transport of electrical current while limiting an electrical leakage or shunt of neighboring contact structures of opposite charge collecting type. Therefore, an electrically non isotropic material, having for example a higher conductivity in the layer growth direction Z than in directions X, Y, perpendicular to it, might be beneficial in embodiments.

The thickness t of the multifunctional protection layer 8 is preferably greater than 1 nm, preferably greater than 10 nm and may be greater than 1 μm. In variants the thickness t may vary in the plane of the multifunctional protection layer 6.

In all embodiments of the invention, the thickness t of the multifunctional protection layer 8 is between 1 nm and 1 μm, or between 1 nm and 500 nm, and preferably between 10 nm and 200 nm.

The multifunctional protection layer 8 provides also low electrical contact resistance between the semiconducting layer 6 and said layer stack 100, said low contact electrical resistance being preferably less than 1000 mOhm*cm², preferably less than 500 mOhm*cm².

In preferred embodiments, the multifunctional protection layer 8 has an electrical resistivity between 0.005 Ohm*cm and 20000 Ohm*cm, preferably between 0.01 Ohm*cm and 10000 Ohm*cm, even more preferably between 0.05 Ohm*cm and 5000 Ohm*cm.

The optimized value of the electrical resistivity depends on solar cell properties like voltage and current at the maximum power point MPP as well as the width w of the trenches 20 in the charge collecting layer stack 100.

An optimized value can be calculated by using a 1-Diode model of a solar cell.

$$J ( V ) = {J}_{0} ( {e}^{\frac{q ( V - J ( V ) {R}_{Tot} )}{n k T}} - 1 ) + \frac{V - J ( V ) {R}_{Tot}}{{R}_{shunt}} - {J}_{l} \qquad ( 2 )$$

$${R}_{Tot} = {R}_{series cell} + {R}_{series MFL} ; {R}_{series MFL} \sim \frac{{ρ}_{MFL}}{t} \qquad ( 3 )$$

$${R}_{shunt} = {R}_{shunt MFL} ; {R}_{shunt MFL} \sim {ρ}_{MFL} w \qquad ( 4 )$$

The parameters used in these formulas 2-4 are:
J (V): solar cell current density,
Jₗ: photocurrent density,
J₀: diode saturation current density,
V: solar cell voltage,
q: basic electric charge,
n: ideality factor,
k: Boltzmann constant,
ρ_{MFL}: resistivity of the multifunctional protective layer,
t: MFL layer thickness,
W: gap between neighboring contact structures (IS1, IS2),
R_{series cell}: including all relevant series resistances of the solar cell without MFL,
R_{series MFL}: series resistances related to MFL, including contact resistances,
R_{shunt MFL}: shunt resistance due to lateral conductivity of the MFL, the shunt resistance of the solar cell without MFL is considered as negligible!

Hereafter (E1, E2), two typical, non-limiting, exemplary realizations are mentioned here, in which the multifunctional protection layer 8 has the following properties:
E1) a multifunctional protection layer 8 made of SnO₂: Sb and having a thickness t between 5 nm-200 nm, possibly between 10 nm-200 nm, and a resistivity between 0.01 Ohm*cm and 10000 Ohm*cm;
E2) a multifunctional protection layer 8 made of TiOxNy and having a thickness t between 5 nm-200 nm and a resistivity between 0.01 Ohm*cm and 10000 Ohm*cm; with x and y being numbers between 0 and 2, possibly equal to 2, i.e. 0<x, y≤2.

The thickness t of the multifunctional protection layer 8 has to be chosen such that on the one hand it fulfills sufficiently its protective effect and on the other hand reduces electrical losses due to resistive, ohmic losses between the doped semiconducting layer 6 and the charge collecting layer stack 100, including contact resistance and series resistance, as well as the losses due to a shunt, leakage current between charge collecting structures IS1 and IS2.

In a preferred embodiment, the multifunctional protection layer 8 is a continuous, full area non-structured layer and covering completely the doped silicon layer stack 6. In the case of a Heterojunction IBC solar cell featuring a tunnel-junction between n- and p-doped silicon layers in the overlapping area where layer 6″ is at least partially covering the structured portions 6′ the multifunctional protection layer 8 is in direct contact with layer 6″.

In a variant, the multifunctional protection layer 8 may be partially etched, for example the thickness t of the multifunctional protection layer 8, in at least one X-Z and/or Y-Z plane in the trenches 20, may be reduced in thickness relative to the thickness t of the remaining portion of the multifunctional protection layer 8 that is not facing the trenches 20.

In an embodiment the multifunctional protection layer 8 comprises at least two different sublayers 8′, 8″. Using at least one sublayer 8′, 8″ improves the contact resistance in the device 1. The different sublayers 8′, 8″ can differ in its material composition, in its state of oxidational and/or its doping level.

In variants, the at least two sublayers 8′, 8″ may have different electrical properties, for example possibly different vertical and/or horizontal electrical resistance. In other variants, the at least two sublayers may have different resistance to physical or chemical deterioration, such as resistance to water vapor or metal ion diffusion. The sublayers 8′, 8″ have, in most embodiments, different optical transmission T and/or different contact resistances to the semiconducting layer 6 and the conductive layer stack 100.

On said multifunctional protection layer 8, to the side away from said substrate 2, a structured charge collecting layer stack 100, defined also as layer stack, is arranged.

The layer stack 100 comprises vertical trenches 20 to separate electrically the first-type charge collecting structures IS1 and the second-type charge collecting structures IS2, said trenches 20 having a minimal width w.

The trenches 20 have preferably a rectangular 2D configuration in a horizontal X-Y plane, as illustrated in FIG. 1. The trenches 20 surround a predetermined number of first-type charge collecting structures IS1 or second-type charge collecting structures IS2 It is understood that the trenches 20 as described herein must not have necessarily smooth internal surfaces and may have variable widths in function of the vertical direction. For example, a vertical cross section, i.e., in a vertical X-Z and/or a Y-Z plane, of the trenches 20 may have a V-shape or a step-shape comprising at least one step, such as a staircase shape.

In an embodiment, said layer stack 100 comprises at least one conductive layer 10, 12.

In an embodiment the solar cell has a patterned resist layer comprising first and second type apertures 14b, 14c, the second type apertures defining said trenches 20. In an embodiment, the solar cell has conducting pads 16, 16′, that are arranged on said resist layer 14 and that extend into said first type apertures 14b and are in contact with said layer stack 100.

In an advantageous embodiment, at least one of the conductive layers 10, 12 is a metal layer.

In an advantageous embodiment, at least one of the conductive layers 10, 12 is a transparent conductive layer.

In an embodiment, said stack of layers 100 comprises at least one transparent conductive oxide (TCO).

In an embodiment no transparent conductive oxide (TCO) is deposited, but only a metal layer is deposited.

In an embodiment, the multifunctional protection layer 8 is made of an electrically isotropic material having the same conductivity and resistivity in X-, Y- and Z-direction.

In an embodiment, the multifunctional protection layer 8 is made of an electrically anisotropic layer, wherein the conductivity of the material in Z-direction is higher than in the plane, defined by the X-, Y-axes. For example, the resistivity of the material in Z-direction is in the range of 0.01 Ohm*cm to 10 Ohm*cm and the resistivity in the horizontal X-Y plane in the range of 10 Ohm*cm to 10k Ohm*cm.

In an embodiment, the multifunctional protection layer 8 is made out of more than one sublayer. The sublayers may be made out of the same material or of different materials. The difference in the material might be also to be found in different oxidation, nitration of carbonization states. The difference may also to be found in different doping states with an otherwise same base material.

In an embodiment, the multifunctional protection layer is made of materials including at least partially TiNx, TiOx, TiOxNy, SnOx, ZnO, ZnSNxOy, ICO, MoOx, ITO, IO, IZO, IWO, WO, IZrO, TaNx, TaOx, TiZrxNy and wherein x and y are between 0 and 3, possibly equal to 3, i.e. 0<x, y≤3.

For reasons of clarity the chemical terms of the materials are listed here: TiN:titanium-nitride; TiOx:titanium-oxide; TiOxNy:titanium-oxy-nitride; SnOx:tin-oxid; ZnOx:zinc-oxide; ZnSNxOy:zinc-sulfide-oxy-nitride; ICO:indium-cerium-oxide; MoOx:molybdenum-oxide; ITO:Indium-tin-oxide; IO:indium-oxide; IZO:indium-zinc-oxide; IWO:indium-tungsten-oxide; WO:tungsten-oxide; IZrO:indium-zirconium-oxide; TaNx:tantalum-nitride; TaOx:tantalum-oxide; TiZrxNy:titanium-zirconium-nitride.

That means that the interdigitated back contact (IBC) photovoltaic device 1 comprises:
on said semiconducting layer 6, a continuous multifunctional protection layer 8 that has a higher resistance against physical and chemical degradation than the to be protected semiconducting layer 6, said multifunctional protection layer 8 being electrically conductive, wherein the multifunctional protection layer 8 is made, at least partially, of at least one of: TiNx, TiOx, TiOxNy, SnOx, ZnO, ZnSNxOy, ICO, MoOx, ITO, IO, IZO, IWO, WO, IZrO, TaNx, TaOx, TiZrxNy and wherein x and y are between 0 and 3, possibly equal to 3, i.e. 0<x, y≤3, the semiconducting layer 6 being preferably a doped silicon layer;
on said multifunctional protection layer 8, a structured charge collecting layer stack 100 is arranged, comprising vertical trenches 20 to separate electrically the first-type charge collecting structures IS1 and the second-type charge collecting structures IS2, this layer stack 100 comprising at least one conductive layer 10, 12.

In an embodiment, the material of the multifunctional protection layer 8 is doped with at least one of the following elements: Sb, F, Al, In, Ga, Mg, B, P, Zn, Ta, Y, H, Ce.

In an embodiment, the multifunctional protection layer 8 has a thickness t between 1 nm and 1 μm, preferably between 1 nm and 500 nm, more preferably between 1 nm and 200 nm.

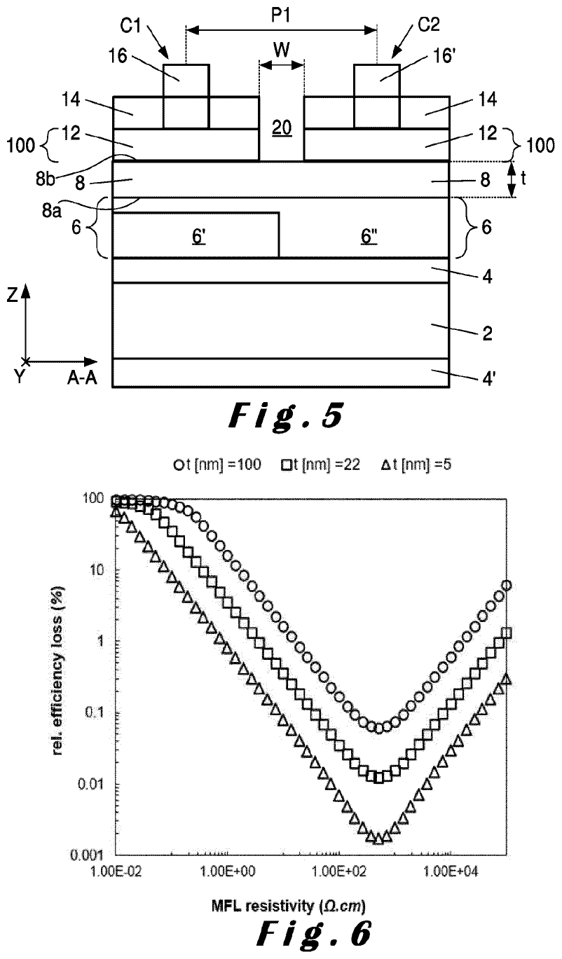

FIG. 5 shows experimental results of a multifunctional protection layer 8. The results show, for different thicknesses t of 5 nm (Δ), 22 nm (¤) and 100 nm (O) that the relative efficiency loss, expressed in %, is minimal for a certain electrical resistivity of the multifunctional protection layer 8. The results were obtained by using the electrical one-diode model of a solar cell as pointed out in formulas 1-3. The results show that the invention allows to provide a multifunctional protection layer 8 that protects the semiconducting layer 6 and that still has an acceptable efficiency.

The invention is also achieved by a photovoltaic system comprising at least two interdigitated back contact (IBC) photovoltaic devices 1, as described herein, that are interconnected by conductors and wherein conducting pads of the first type 16 of the first cell are connected to conducting pads of the second type 16′ of the second cell by that establishing a series connection of accordingly connected devices. In a variant, the conducting pads of the first or second type 16, 16″ of the first cell are connected respectively to conducting pads of the first or second type 16, 16′ of the second cell and by that establishing a parallel connection of accordingly connected devices. Conducting wires connecting the conducting pads 16, 16′ extend preferably mainly in said longitudinal direction and so have a much larger extension in the longitudinal X direction than in the lateral Y direction.

In another aspect the invention is achieved by a method for manufacturing an interdigitated back contact (IBC) photovoltaic device 1 as described herein. The interdigitated back contact (IBC) photovoltaic device 1 comprises a substrate 2 defining a plane X-Y and, parallel to said plane X-Y, a longitudinal A-A and a lateral B-B direction, illustrated in FIG. 1, orthogonal to said lateral direction A-A and comprising the steps A-F of:
Step A: providing a substrate 2 of a first- or second type doping being an n-type or a p-type doping and having a front side 2a and a back side 2b and realizing on said back side 2b a semiconducting structure 6 comprising a first-type doped structured semiconducting layer 6′ consisting in a plurality of individual doped portions 6′ of a first type doping n- or p and a second-type doped semiconducting layer 6″ having a doping of the other type p- or n than said first type doping n- or p, to provide alternating electrical charge-types of semiconducting contacts;
Step B: realizing an electrically conductive multifunctional protection layer 8 on top (i.e. in the positive Z direction) of said doped semiconducting layer 6, the multifunctional protection layer 8 having a metal ion diffusion coefficient D1, that is lower than the metal ion diffusion coefficient D2 at the same temperature in said semiconducting layer 6 at the same temperature, so that the multifunctional protection layer 8 is less vulnerable to physical and/or chemical degradation than the to be protected semiconducting layer 6, to protect the semiconducting layer 6, the multifunctional protection layer 8 being further configured to allow, in the to be realized photovoltaic device 1 in operation, vertical transport of electrical current through its thickness t while limiting electrical leakage or shunt of neighboring charge collecting structures IS1, IS2 of opposite charge collecting types;
Step C: realizing, on said multifunctional protection layer 8, a stack of layers 100 comprising at least, one of a conductive layer 10, 12;
Step D: realizing on said layer stack 100 a patterned resist layer 14, so that the patterned resist layer 14 comprises resist parts 14a and resist apertures 14b, 14c;
Step E: applying a plurality of conductive pads 16, 16′ onto said resist layer 14, and so that the conductive pads 16, 16′ fill said resist apertures 14b making electrical contact to said conductive layer stack 100;
Step F: etching of the stack of layers 100, in areas specified by apertures 14c in the isolation resist layer 14, having a thickness d14, so as to create trenches 20 having a minimal width w, to electrically separate first type charge collecting structures IS1 from second type charge collecting structures IS2.

It is thus understood that, as the multifunctional protection layer 8 is not part of the layer stack 100, the multifunctional protection layer 8 is preferably not etched at all, at least not fully, which provides a protection at the bottom of the trenches 20 made in the layer stack 100.

In a variant, the multifunctional protection layer 8 may be etched, for example, at a depth smaller than 1/10^{th} of its thickness t.

In an embodiment of the method, optionally a step G is performed consisting in the realization of a plurality of holes 200, defined by apertures 14d in the isolation resist layer 14, up to said multi-functional protection layer 8. In embodiments said holes 200 have diameters between 2 μm and 500 μm.

In variants, the plurality of holes 200 may extend to a depth d2 in the multifunctional protection layer 8, and this depth d2 is always smaller than 1/10^{th} of the thickness t of the multifunctional protection layer 8.

Said plurality of holes 200 holes can allow to increase the bi-faciality of embodiments of the photovoltaic cell 1 of the invention.

1. An interdigitated back contact photovoltaic device comprising:
a plurality of first-type charge collecting structures;
a plurality of second-type charge collecting structures;
a substrate defining an X-Y plane defined by two orthogonal directions X and Y, and a vertical direction Z orthogonal to the X-Y plane;
a doped semiconducting layer on said substrate the doped semiconducting layer comprising
a first-type doped structured semiconducting layer consisting of a plurality of n-doped or p-doped portions, and
a second-type doped semiconducting layer of the other doped-type of said first-type doped structured semiconducting layer;
a continuous, electrically conductive, multifunctional protection layer configured to protect said doped semiconducting layer, said continuous, electrically conductive, multifunctional protection layer being disposed on the doped semiconducting layer, the continuous, electrically conductive, multifunctional protection layer having a metal ion diffusion coefficient that is lower than a metal ion diffusion coefficient in said doped semiconducting layer at the same temperature, so that the continuous, electrically conductive, multifunctional protection layer is less vulnerable to one or more of physical degradation and chemical degradation than the doped semiconducting layer; and
a structured charge collecting layer stack disposed on the continuous, electrically conductive, multifunctional protection layer, the structured charge collecting layer stack comprising vertical trenches to electrically separate the first-type charge collecting structures and the second-type charge collecting structures, the structured charge collecting layer stack comprising at least one conductive layer.

2. The interdigitated back contact photovoltaic device according to claim 1, wherein the metal ion diffusion coefficient of the continuous, electrically conductive, multifunctional protection layer is lower than 5×10⁻¹⁰ cm²s⁻¹.

3. The interdigitated back contact photovoltaic device according to claim 1, further comprising a patterned isolating resist layer disposed on top of the structured charge collecting layer stack, the patterned isolating resist layer comprising first-type apertures and second-type apertures, the second-type apertures in the isolation patterned isolating resist layer defining said vertical trenches.

4. The interdigitated back contact photovoltaic device according to claim 1, further comprising conducting pads that are disposed on said resist layer and that extend, in said first-type apertures, up to and in contact with said structured charge collecting layer stack.

5. The interdigitated back contact photovoltaic device according to claim 1, wherein said continuous, electrically conductive, multifunctional protection layer has an electrical resistivity between 0.005 Ohm*cm and 20000 Ohm*cm.

6. The interdigitated back contact photovoltaic device according to claim 1, wherein the continuous, electrically conductive, multifunctional protection layer provides low electrical contact resistance between the doped semiconducting layer and said structured charge collecting layer stack, said low electrical contact resistance being less than 1000 mOhm*cm².

7. The interdigitated back contact photovoltaic device according to claim 1, wherein said continuous, electrically conductive, multifunctional protection layer is a transparent layer having an optical transparency at least in a wavelength range between 900 nm and 1200 nm.

8. The interdigitated back contact photovoltaic device according to claim 1, wherein said continuous, electrically conductive, multifunctional protection layer is a reflective layer having a reflectivity higher than 10%, at least in a wavelength range between 900 nm and 1200 nm.

9. The interdigitated back contact photovoltaic device according to claim 1, wherein the continuous, electrically conductive, multifunctional protection layer is made of an electrically isotropic material.

10. The interdigitated back contact photovoltaic device according to claim 1, wherein the continuous, electrically conductive, multifunctional protection layer is made of an electrically anisotropic material, wherein the conductivity of the electrically anisotropic material is higher in the Z-direction than in the X-direction or the Y-direction.

11. The interdigitated back contact photovoltaic device according to claim 1, wherein said at least one conductive layer is a transparent conductive layer.

12. The interdigitated back contact photovoltaic device according to claim 1, wherein continuous, the electrically conductive, multifunctional protection layer is at least partially made, of at least one of: TiNx, TiOx, TiOxNy, SnOx, Zno, ZnSNxOy, ICO, MOx, ITO, IO, IZO, IWO, WO, IZrO, NiO, TaNx, TaOx, and TiZrxNy, and
wherein 0< (x, y)≤3.

13. The interdigitated back contact photovoltaic device according to claim 1, wherein the continuous, electrically conductive, multifunctional protection layer is doped with at least one of the following elements: Sb, F, Al, In, Ga, Mg, B, P, Zn, Ta, Y, Ce, and H.

14. The interdigitated back contact photovoltaic device according to claim 1, wherein the thickness of said continuous, electrically conductive, multifunctional protection layer is between 1 nm and 1 μm.

15. A photovoltaic system comprising:
at least two interdigitated back contact photovoltaic devices according to claim 1, the at least two interdigitated back contact photovoltaic devices being interconnected by conductors,
wherein conducting pads of a first type of a first interdigitated back contact photovoltaic device of the at least two interdigitated back contact photovoltaic devices are connected to conducting pads of a second type of a second interdigitated back contact photovoltaic device of the at least two interdigitated back contact photovoltaic devices by establishing a series connection of accordingly connected interdigitated back contact photovoltaic devices.

16. A method for manufacturing the interdigitated back contact photovoltaic device according to claim 1, the method comprising steps of:
step A: providing the substrate of a first-type doping or a second-type doping that is an n-type doping or a p-type doping and having a front side and a back side, and providing the doped semiconducting layer on the back side of the substrate, the doped semiconducting layer comprising the n-doped or p-doped portions of said first-type doping and the second-type doped semiconducting structure of second-type doping that is of the other type than said first-type doping, to provide alternating electrical charge-types of semiconducting contacts;
step B: providing the continuous, electrically conductive multifunctional protection layer on top of said doped semiconducting layer, the continuous, electrically conductive multifunctional protection layer having the metal ion diffusion coefficient that is lower than the metal ion diffusion coefficient at the same temperature in said doped semiconducting layer at the same temperature, so that the continuous, electrically conductive multifunctional protection layer is less vulnerable to one or more of the physical degradation and the chemical degradation than the doped semiconducting layer;
step C: providing the structured charge collecting layer stack on said continuous, electrically conductive multifunctional protection layer comprising the at least one conductive layer;
step D providing a patterned resist layer on the structured charge collecting layer stack so that the patterned resist layer comprises resist parts and resist apertures;
step E: applying a plurality of conductive pads onto said patterned resist layer so that the conductive pads fill said resist apertures, making electrical contact to said structured charge collecting layer stack;
step F: etching of the structured charge collecting layer stack in areas specified by other apertures in the isolation resist layer to create trenches having a minimal width to electrically separate first-type charge collecting structures rom second-type charge collecting structures.

17. The method according to claim 16, wherein the continuous, electrically conductive, multifunctional protection layer is at least partially made of at least one of: TiNx, TiOx, TiOxNy, SnOx, Zno, ZnSNxOy, ICO, MoOx, ITO, IO, IZO, IWO, WO, IZrO, NiO, TaNx, TaOx, and TiZrxNy, and
wherein 0<x, y≤3.

18. The method according to claim 16, wherein the continuous, electrically conductive, multifunctional protection layer is doped with at least one of the following elements: Sb, F, Al, In, Ga, Mg, B, P, Zn, Ta, Y, Ce, and H.

19. A photovoltaic system comprising:
at least two interdigitated back contact photovoltaic devices according to claim 1, the at least two interdigitated back contact photovoltaic devices being interconnected by conductors,
wherein conducting pads of a first type or a second type of a first interdigitated back contact photovoltaic device of the at least two interdigitated back contact photovoltaic devices are respectively connected to conducting pads of the first type or the second type of the second interdigitated back contact photovoltaic device of the at least two interdigitated back contact photovoltaic devices and by establishing a parallel connection of accordingly connected interdigitated back contact photovoltaic devices.
